(19) United States
(12) Patent Application Publication
(10) Pub. No.: US 2011/0163405 A1
(43) Pub. Date: Jul. 7, 2011

(54) Image Sensor with Pixel Wiring to Reflect Light

(76) Inventor: Hiok Nam TAY, Singapore (SG)

(21) Appl. No.: 13/040,321

(22) Filed: Mar. 4, 2011

Related U.S. Application Data
(63) Continuation-in-part of application No. 13/011,864, filed on Jan. 22, 2011.
Application No. 13/011,864 is a continuation of application No. 11/716,172, filed on Mar. 9, 2007, now abandoned.

(51) Int. Cl. H01L 27/146

(52) U.S. Cl. 257/448; 257/E27.131

(57) ABSTRACT

An image sensor with a plurality of photodiode pixels supported by a substrate. At least one of the photodiode pixels includes a reflective element that prevents light from traveling onto an adjacent photodiode pixel. The reflective element may be a floating contact on a dielectric barrier that insulates the contact from a substrate. The reflective element may be a via that may or may not be an essential part of an electrical connection between two or more integrated devices. The reflective element may be elongated in a horizontal section parallel to the substrate to maximize the reflective surface area and thus longer than standard vias and contacts. The reflective element may be non-rectilinear. The via may be directly above but insulated from a conductor by a dielectric layer thinner than an inter-metal dielectric (IMD) thickness between interconnect layers, and may straddle one or more conductors.

### CROSS-REFERENCE TO RELATED APPLICATIONS

This application is a Continuation-in-Part of U.S. patent application Ser. No. 13/011,864 filed on Jan. 22, 2011, which is a continuation of U.S. patent application Ser. No. 11/716,172 filed on Mar. 9, 2007.

### BACKGROUND OF THE INVENTION

1. Field of the Invention

The subject matter disclosed generally relates to the field of semiconductor image sensors.

2. Background Information

Photographic equipment such as digital cameras and digital camcorders may contain electronic image sensors that capture light for processing into still or video images, respectively. Electronic image sensors typically contain millions of light capturing elements such as photodiodes. The photodiodes are arranged in a two-dimensional pixel array.

FIG. 1 shows an enlarged perspective view of adjacent pixels in a photodiode array. Each pixel has a photo-absorption region 1 and 2, respectively, that absorbs incoming light 3 and creates electron hole pairs.

Wires 4 are formed on the surface of the array to route electrical signals to the individual pixels of the array. The wires 4 are spaced apart to form windows that allow light to travel into the photo-absorption regions 1 and 2. In the center of the array the light impinges onto the photo-absorption regions in an essentially perpendicular direction. In the outer corner regions of the array the light travels at an inclined direction such that some of the light that travels through the window of the first photo-absorption region 1 impinges on the second photo-absorption region 2, as shown in FIG. 1. This will cause the pixel of region 2 to inadvertently sense light from the first region and result in a lower quality picture.

It would be desirable to isolate pixels of a photodiode array to inhibit inadvertent light absorption from adjacent pixels.

### BRIEF SUMMARY OF THE INVENTION

An image sensor with an array of photodiodes pixels. At least one of the photodiodes pixels includes a reflective element that reflects light onto a photo-absorption region of the photodiode.

### BRIEF DESCRIPTION OF THE DRAWINGS

FIG. 1 is an illustration of an image sensor of the prior art;

FIG. 2 is a schematic of an image sensor;

FIG. 3 is an illustration of a photodiode pixel;

FIG. 4 is an illustration similar to FIG. 3 with a routing wire removed;

FIG. 5 is an illustration similar to FIG. 4 showing light being reflected from a hanging wire;

FIGS. 6 to 8 are illustrations of alternate embodiments of the photodiode pixel.

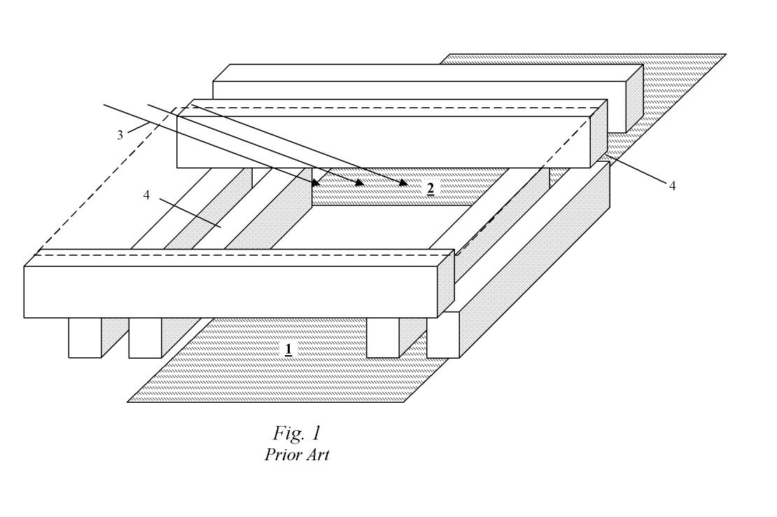

### DETAILED DESCRIPTION

Disclosed is an image sensor with a plurality of photodiode pixels. At least one of the photodiode pixels includes a reflective element that has a reflective surface that prevents light from traveling onto an adjacent photodiode pixel. The reflective element may be a floating contact on a dielectric barrier that insulates the contact from a substrate. The reflective element may be a via that may or may not be an essential part of an electrical connection between two or more integrated devices. The reflective element may be elongated in a horizontal section parallel to the substrate to maximize the reflective surface area and thus longer than standard vias and contacts. The reflective element may be non-rectilinear. The via may be directly above but insulated from a conductor by a dielectric layer thinner than an inter-metal dielectric (IMD) thickness between interconnect layers, and may straddle one or more conductors.

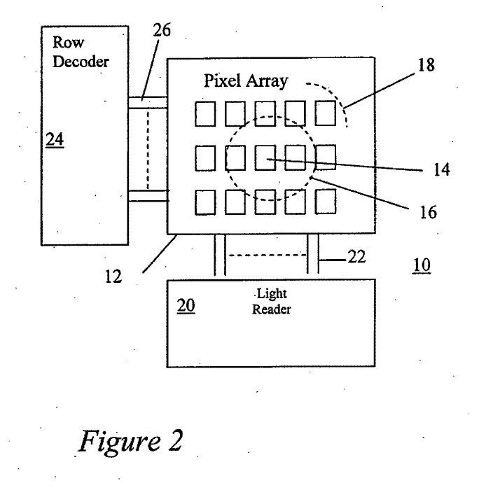

Referring to the drawings more particularly by reference numbers, FIG. 2 shows an image sensor 10. The image sensor 10 includes a photodiode pixel array 12 that contains a plurality of individual photodiodes 14. The photodiodes 14 are typically arranged in a two-dimensional array of rows and columns. The array 12 has a center area 16 and corner areas 18.

The photodiode array 12 is typically connected to a light reader circuit 20 by a plurality of routing wires 22. The array 12 is connected to a row decoder 24 by routing wires 26. The row decoder 24 can select an individual row of the array 12. The light reader 20 can then read specific discrete columns within the selected row. Together, the row decoder 24 and light reader 20 allow for the reading of an individual photodiode 14 in the array 12. Signals read from the photodiodes 14 may be processed by other circuits such as a processor (not shown) to generate a visual display.

The image sensor 10 and other circuitry may be configured, structured and operated in the same, or similar to, the corresponding image sensors and image sensor systems disclosed in U.S. Pat. No. 6,795,117 issued to Tay, which is hereby incorporated by reference.

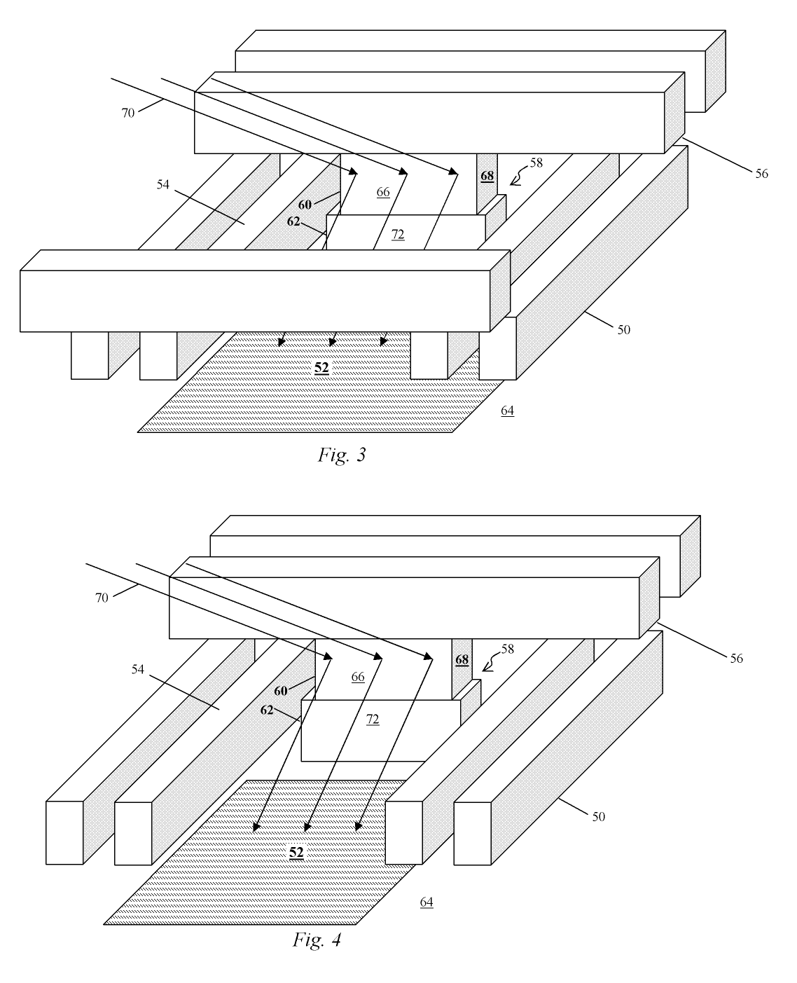

FIGS. 3 and 4 show a photodiode pixel 14. The pixel includes a photo-absorption region 52 of a photodiode. By way of example, the photo-absorption region 52 may comprise a lightly doped n-type material. Routing wires 54 and routing wires 56 extend within two different interconnect layers that are parallel to the substrate 64 and that are mutually adjacent among a plurality of horizontal interconnect layers of a multi-layer interconnect typical of integrated circuits. Some of the routing wires are connected to the row decoder 24 and light reader 20 shown in FIG. 2.

Adjacent to one or more of the wires 54 is a reflective element 58. The reflective element 58 may include a via 60 and may further include a hanging wire 62. The reflective element 58 may be located between the wire 56 and a substrate 64. Each via 60 may include a width surface 66 and a thickness surface 68. The hanging wire 62 belongs to the same horizontal interconnect layer as wires 54, such that the hanging wire 62 and wires 54 are formed at the same time during fabrication of the image sensor and have the same distance from the substrate 64. The via 60 is under one horizontal interconnect layer and on another. The via 60 may be fabricated by same process step(s) that fabricate(s) a standard via of a multilevel interconnect in a periphery circuit of the image sensor, such as the row decoder 24, the light reader 20, an analog-to-digital converter (not shown) or an I/O buffer (not shown). The standard vias (and likewise the standard contacts in the periphery circuits) typically have equal dimensions in two mutually perpendicular directions parallel to the substrate 64.

The reflective element 58 comprises a reflective material such as a metal to reflect incoming light 70 onto the photo-absorption region 52. By way of example, the metal may be copper, aluminum or any other metal used in the fabrication of semiconductor circuits.

In the outer areas 18 of the pixel array 12 light travels at an angle normal to the top surface of the image sensor. The reflective element 58 prevents the light from impinging upon an adjacent photodiode. The reflective element 58 also reflects the light onto the photo-absorption region 52 to maximize the amount of light that impinges region 52. The via 60 may have a width surface 66 to thickness surface 68 aspect ratio that maximizes the area of reflective surface 66. By way of example, the width to thickness ratio greater than 1, such as 1.5. This is to be distinguished from prior art vias which require a 1 to 1 ratio. Viewing it another way, the via 60 is elongated in such a way that a horizontal section (i.e. one that is parallel to the substrate 64) of the via 60 is longer in a direction than in a perpendicular direction. The via 60 also is longer in at least one direction within a horizontal section of itself compared with a standard via that can be found in a periphery circuit of the image sensor (i.e. outside the photodiode array 12) and that has same vertical distance from the substrate 64 as the via 60. Although aspect ratio greater than 1 is shown and described, it is to be understood that the invention may utilize aspect ratios equal to or less than one for the via 60.

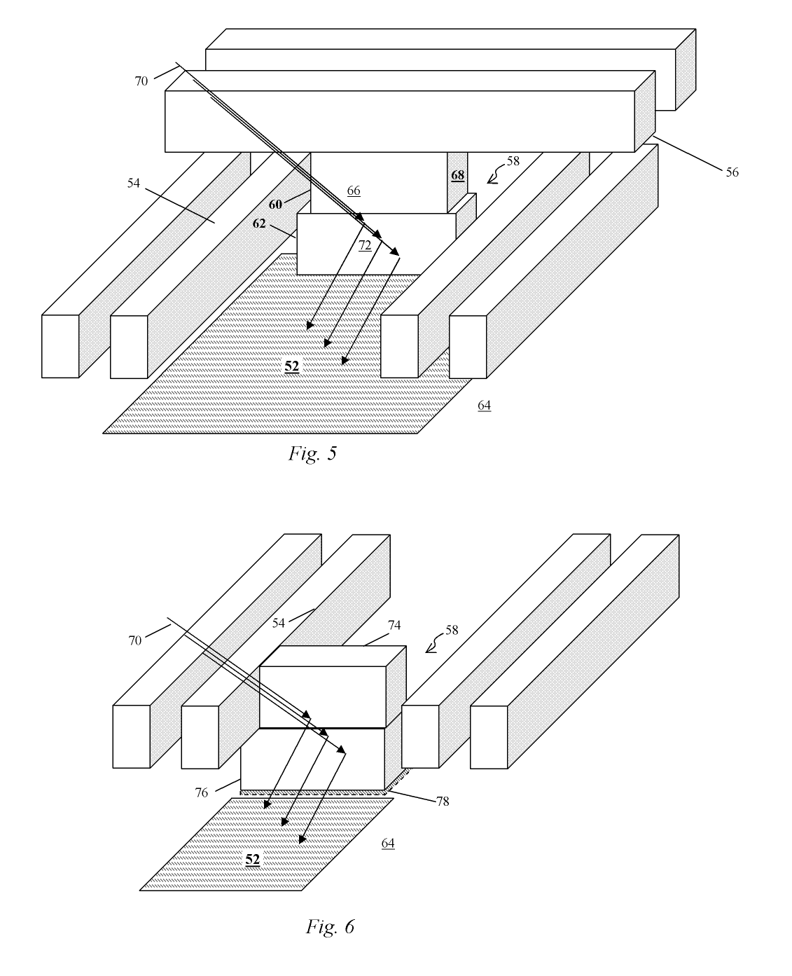

The via 60 illustrated in FIG. 5 does not conduct DC current flowing perpendicularly to the substrate 64. It is clear that such DC current is impossible as it would charge up the hanging wire 62 under itself indefinitely since there is not other entrance/exit for the DC current into/out of the hanging wire 62. The via 60 as illustrated in FIG. 5 does not have a purpose of forming connectivity, but rather to reflect light sideways. In general, the via 60 needs not be an essential part of an electrical connection from an integrated device to another. Where a gap exists between the photo-absorption region 52 and an adjacent photodiode and between two mutually adjacent interconnect layers, the via 60 may be disposed therein to at least partially plug the gap to prevent light from crossing towards the adjacent photodiode as long as functionality of the photodiode array 12 is not affected.

Nevertheless, use of the elongated via is by no means limited this way. The ordinary artisan will understand from the illustration of FIG. 5 that the elongated via as represented by the via 60 has an advantage of providing a wider area in the lateral surface 66 to reflect more light onto the light-absorption area 52 and to allow less light to cross over to the photodiode of an adjacent pixel than if the abovementioned aspect ratio were 1-to-1, and that this advantage is independent of whether the elongated via is an essential part of an electrical connection between a pair of integrated devices. The elongated via may be installed as an essential part of an electrical connection from an integrated device to another. Likewise, he will also understand that this advantage is independent of whether a horizontal conductor such as the hanging wire 62 is under the elongated via.

As shown in FIG. 5, deep penetrating light can be reflected by the hanging wire 62. The hanging wire 62 is not an essential part of any electrical connection between any integrated device to any other integrated device. Thus, removing the hanging wire 62 will not affect functionality of any integrated device in the photodiode array 12.

FIG. 6 shows an alternate embodiment, that has a hanging wire 74 and a floating contact 76. The floating contact 76 is formed on a dielectric barrier 78. By way of example, the dielectric barrier 78 may be a layer of thick oxide such as a LOCOS or a shallow-trench isolation (STI). The barrier 78 electrically isolates the hanging wire 74 from the image sensor substrate 64. As shown in FIG. 6, the hanging wire 74 and the floating contact 76 each and together reflect light rays into the light-absorption region 52 as well as prevent light rays from straying into an adjacent photodiode.

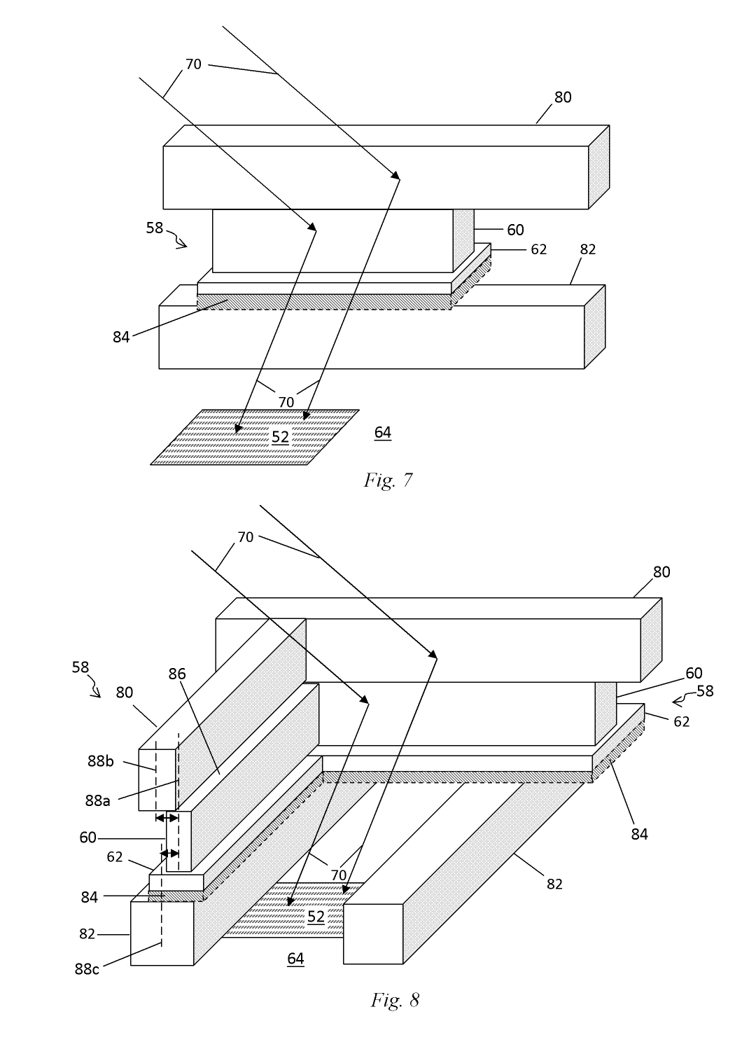

FIG. 7 shows another alternate embodiment, where the via 60 and hanging wire 62 are located between an upper conductor 80 and a lower conductor 82 that respectively belong to one of two mutually adjacent horizontal interconnect layers. Thus conductors 80, 82 are separated in a vertical direction (i.e. a direction perpendicular to the substrate) by a height of a standard via found in a periphery circuit of the image sensor connecting a routing wire at same height as the lower conductor 82 from the substrate 64 and a next higher routing wire at same height as the upper conductor 80 from the substrate 64. The via 60 reaches the same height above the substrate as the standard via. The hanging wire 62 has only a fraction of a thickness of the upper conductor 80 in the vertical direction. The hanging wire 62 may be separated from the lower conductor 82 by a layer of dielectric 84 to prevent electrical shorting between the upper 80 and lower 82 conductors. The layer of dielectric 84 may have a dielectric thickness less than half as thick as the lower horizontal conductor, and preferably less than 2,500 Angstroms, and more preferably within 1,000 Angstroms±20%, in the same direction. The layer of dielectric 84 may have a dielectric thickness less than a third of an intermetal dielectric thickness, which is a vertical distance from bottom of the upper conductor 80 and to top of the lower conductor 82.

The layer of dielectric 84 and the hanging wire 62 are preferably formed by process steps for forming a conventional metal-to-metal (MIM) capacitor (such as according to U.S. Pat. No. 6,876,028 and No. 7,317,221) in a analog or mixed-signal integration circuit wherein a process step(s) for forming the lower conductor 82 also forms a metallic bottom plate of the MIM capacitor, a process step(s) for forming the layer of dielectric 62 also forms a layer of dielectric insulating the bottom plate from a metallic top plate of the MIM capacitor, and a process step(s) for forming the hanging wire 62 also forms the top plate of the MIM capacitor. Such a MIM capacitor may be found in the row decoder 24, the light reader 20, an analog-to-digital converter (ADC) (not shown in FIG. 2) within the image sensor, or a switched-capacitor amplifier (not shown) within the image sensor. The lower conductor 82 thus will have same distance from the substrate 64 as the bottom plate; the thickness of the layer of dielectric 84 will be same as a distance of separate between the bottom and top plates; and the hanging wire 62 will have same distance from the substrate 64 as the top plate as well as share the same thickness in the direction perpendicular to the substrate 64.

During formation of the via 60, specifically during a step of forming a via hole or trench (e.g. by etching in an insulator) into which a metal is subsequently deposited to form the via 60, were it not for the hanging wire 62, the via hole or trench would penetrate all the way through to the lower conductor 82, which would subsequently cause a short circuit between the lower conductor 82 and the upper conductor 82 when the metal is deposited. The hanging wire 62 acts as an etch stop for the via hole or trench, thus avoiding the short circuit.

FIG. 8 shows yet another alternate embodiment. In FIG. 8, a pair of lower conductors 82 extend parallel to the substrate 64 and perpendicularly to an upper conductor 80. The upper conductor 80 has a branch that extends parallel to the lower conductors 82 and, in particular, at least partially overlaps one (on the left)) of the lower conductors 82 when looking down at the substrate 64 and in a direction perpendicular to the substrate 64. The via 60 takes an L-shape under the upper conductor 80. It should be noted, however, that the via 60 need not be wholly under the upper conductor 80. In other words, the upper conductor 80 may be only partially overlapping the via 60. As shown in FIG. 8, a branch of the via 60 under the branch of the upper conductor 80 has a top surface 86 that is not under the upper conductor 80. Between the via 60 and the upper conductor 80 there can a lateral offset measured in a vertical section across both and between the respective vertical centerlines 88a, 88b. This lateral offset may vary from one pixel to another and, in particular, may increase from the center area 16 to the corner areas 18 of the photodiode array 12. Likewise, between the vertical centerlines 88a, 88c in the same vertical section through the hanging wire 60 and the lower conductor 82, respectively, there can be a lateral offset and this lateral offset may vary from one pixel to another and may increase from the center area 16 to the corner areas 18. In general, the relative lateral position of the via 60 to any one of the upper conductor 80 and lower conductor 82 can change from pixel to pixel and between the center area 16 and the corner areas 18.

It is also noted that, unlike a MIM capacitor where the top plate is fully contained within the bottom plate when looking down in a direction perpendicular to the substrate 64, the hanging wire 62 as well as the via 60 can have a portion or all of its bottom not directly above a lower conductor 82, as FIG. 8 shows. As shown in FIG. 8, a segment of the via 60 straddles a lower conductor 82 on the right. In general, the via 60 may straddle one or move lower conductor 82. Further, it is not necessary for the hanging wire 62 to be everywhere under the via 60 since where there is no lower conductor 82 directly below the via 60 or nearly so there is no risk of the aforementioned short circuit. Thus, the via 60 may be only partially on hanging wire 62.

It is further noted that the via 60 as shown in FIG. 8 has a horizontal section that is non-rectilinear as well as elongated, and that the via 60 has a larger dimension in at least one direction within the horizontal section compared with a standard via that can be found in a periphery circuit of the image sensor and at the same vertical distance from the substrate 64. The via 60 may be modified to take different shapes of horizontal section and not limited to the L-shape shown. In general, the via 60 may be modified to have one or more bents in a horizontal section, e.g. one bent like the L-shape, or two bents like the U-shape.

It is also noted that the via 60 on the hanging wire 62 which in turn is on the layer of dielectric 84 that insulates the via 60 from the lower conductor 82 is valuable in its own right for reflecting light towards the light-absorption region 52 and for preventing stray light from crossing over to a neighboring pixel, independently of the upper conductor 80.

Like the via 60 shown in FIG. 8, the floating contact 76 may be modified to take a non-rectilinear shape to form a continuous reflective wall shaped around the light-absorptionregion 52 and/or to have one or more bents.

The photodiodes may be constructed with known CMOS fabrication techniques. The photo-absorption region 52 is formed in the substrate 64. Routing wires 54 and the hanging wire 62 are fabricated over the substrate 64. The via 60 is formed next. Routing wires 56 are then fabricated. The order of formation may vary depending on the processes used to create the image sensor.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. An image sensor that includes a pixel array that has a center area and a corner area, comprising:
a photo-absorption region of a photodiode and in a substrate;
a first conductor that extends over and parallel to the substrate;
a via above said first conductor;
a hanging wire partially under said via and partially overlapping said first conductor below itself,
wherein a layer of dielectric less than half as thick as the first conductor in a vertical direction perpendicular to the substrate separates said hanging wire from said first conductor.

2. The image sensor of claim 1, wherein said layer of dielectric is at most 2,500 Angstroms thick in said vertical direction.

3. The image sensor of claim 1, wherein said via reaches as high above the substrate as a standard via in a periphery circuit of said image sensor.

4. The image sensor of claim 1, wherein said via is elongated in a horizontal direction.

5. The image sensor of claim 1, wherein said via is partially directly above said first conductor.

6. The image sensor of claim 1, wherein said via partially overlaps said hanging wire.

7. The image sensor of claim 1, wherein said via has a non-rectilinear horizontal section.

8. The image sensor of claim 1, wherein said via has an L-shaped horizontal section.

9. The image sensor of claim 1, wherein a relative lateral position between said via to said first conductor differs from said center area and said corner area.

10. The image sensor of claim 1, wherein said via is under a second conductor that also extends over and parallel to the substrate.

11. The image sensor of claim 10, wherein said via is partially under said second conductor.

12. The image sensor of claim 10, wherein a relative lateral position between said via to one of said first and second conductors differs from said center area and said corner area.
